(19) United States
(12) Patent Application Publication
(10) Pub. No.: US 2015/0136446 A1
(43) Pub. Date: May 21, 2015

(54) PRINTED CIRCUIT BOARD

(71) Applicant: SAMSUNG ELECTRO-MECHANICS CO., LTD., Gyeonggi-do (KR)

(72) Inventors: Joung Gul RYU, Yongin-si (KR); Sung Taek LIM, Suwon-si (KR); Mi Sun HWANG, Suwon-si (KR)

(73) Assignee: SAMSUNG ELECTRO-MECHANICS CO., LTD., Gyeonggi-Do (KR)

(21) Appl. No.: 14/213,282

(22) Filed: Mar. 14, 2014

(30) Foreign Application Priority Data
Nov. 18, 2013 (KR) 10-2013-0139904

(51) Int. Cl. H05K 1/02; H05K 1/03; H05K 1/18; H05K 1/09; H05K 1/11

(52) U.S. Cl. CPC H05K 1/0271; H05K 1/09; H05K 1/0298; H05K 1/115; H05K 1/181; H05K 1/0306
USPC 174/251

(57) ABSTRACT

Embodiments of the invention provide a printed circuit board having a structure in which a plurality of insulating layers having a metal wiring formed on one surface thereof are stacked, wherein a metal layer is interposed in the insulating layers, in order to improve warpage property of the board.

### CROSS REFERENCE TO RELATED APPLICATION

This application claims the benefit of and priority under 35 U.S.C. §119 to Korean Patent Application No. KR 10-2013-0139904, entitled, “Printed Circuit Board,” filed on Nov. 18, 2013, which is hereby incorporated by reference in its entirety into this application.

### BACKGROUND

1. Field of the Invention

The present invention relates to a printed circuit board, and more particularly, to a printed circuit board having improved warpage property of the board.

2. Description of the Related Art

Generally, a printed circuit board is implemented by wiring copper foil on one surface or both surfaces of a board made of various kinds of thermosetting synthetic resins, fixedly disposing integrated circuits (ICs) or electronic components on the board, and implementing electrical wirings therebetween.

In accordance with miniaturization, densification, and thinness of electronic components, research into thinness and multi-funcionalization of the printed circuit hoard has also been actively conducted.

Particularly, a technology of stacking and mounting multiple semiconductor chips on a single substrate, that is, multi-chip package (MCP) or a technology of stacking multiple substrates having chips mounted thereon, that is, package on package (POP) has been recently proposed. Therefore, the development of the printed circuit hoard having thermal expansion behavior similar to that of the chip and having no warpage problem after mounting the chips has been required.

As one of the technologies for improving the above-mentioned warpage property of the board, a conventional printed circuit board having a structure using prepreg in which glass fiber is impregnated in a resin corn position has been proposed, for example, in Korean Patent Laid-Open Publication No. 10-2011-0026722.

However, since the prepreg has high mechanical strength, but decreases adhesion between the prepreg and a metal, it is difficult to use a semi-additive process (SAP). Instead, a circuit needs to be formed using a tenting process or a modified semi-additive process (MSAP). Therefore, in order to implement a fine line and space of the circuit, an insulating layer having a build-up film form without the glass fiber is required to be used, In this case, since a modulus is low a coefficient of thermal expansion (CTE) is high due to characteristics of the build-up film, warpage property of the board may be deteriorated.

Therefore, the printed circuit board having a structure capable of improving warpage property of the board and implementing a fine circuit has been urgently demanded.

### SUMMARY

Accordingly, embodiments of the present invention provide a printed circuit board capable of improving warpage property of the board and implementing a fine pattern using an insulating layer including a warpage preventing member having a low coefficient of thermal expansion and a high modulus therein.

According to an exemplary embodiment of the present invention, there is provided a printed circuit board having a structure in which a plurality of insulating layers having a metal wiring formed on one surface thereof are stacked, wherein a metal layer is interposed in the insulating layers.

In accordance with an embodiment of the invention, the printed circuit board further includes a hole perforated in the metal layer and a via formed so as to penetrate through the insulating layer and be inserted into the hole.

In accordance with an embodiment of the invention, the hole has a size larger than a diameter of the via.

In accordance with an embodiment of the invention, the hole has a size in a range of 1.1 times to 1.5 times of a diameter of the via.

In accordance with an embodiment of the invention, the hole has a size changed according to a height at which the metal layer is interposed in the insulating layers.

In accordance with an embodiment of the invention, the hole has at least one of a circular shape, an oval shape, or a polygonal shape including a quadrangle.

In accordance with an embodiment of the invention, the metal layer has a thickness in a range of 5% to 35% of a thickness of the insulating layer.

In accordance with an embodiment of the invention, the metal layer includes at least one of iron (Fe), nickel (Ni), tungsten (W), molybdenum (Mo), aluminum (Al), invar, or kovar.

According to another exemplary embodiment of the present invention, there is provided a printed circuit hoard having a structure in which a plurality of insulating layers having a metal wiring formed on one surface thereof are stacked, wherein the insulating layer is configured by first insulating layers made of a resin composition and second insulating layers made of a resin composition having glass fiber impregnated therein, and a metal layer is interposed in the first insulating layers made of the resin composition.

In accordance with an embodiment of the invention, the printed circuit board further includes a hole perforated in the metal layer and a via formed so as to penetrate through the first insulating layer and be inserted into the hole.

In accordance with an embodiment of the invention, the hole has a size larger than a diameter of the via.

In accordance with an embodiment of the invention, the hole has a size in a range of 1.1 times to 1.5 times of a diameter of the via.

In accordance with an embodiment of the invention, the hole has a size changed according to a height at which the metal layer is interposed in the first insulating layers.

In accordance with an embodiment of the invention, the hole has at least one of a circular shape, an oval shape, or a polygonal shape including a quadrangle.

In accordance with an embodiment of the invention, the metal layer has a thickness in a range of 5% to 35% of a thickness of the first insulating layer.

In accordance with an embodiment of the invention, the metal layer includes at least one of iron (Fe), nickel (Ni), tungsten (W), molybdenum (Mo), aluminum (Al), invar, or kovar.

Various objects, advantages and features of the invention will become apparent from the following description of embodiments with reference to the accompanying drawings.

### BRIEF DESCRIPTION OF DRAWINGS

These and other features, aspects, and advantages of the invention are better understood with regard to the following Detailed Description, appended Claims, and accompanying Figures. It is to be noted, however, that the Figures illustrate only various embodiments of the invention and are therefore not to be considered limiting of the invention's scope as it may include other effective embodiments as well.

FIG. 1 is a cross-sectional view of a printed circuit board, in accordance with a first embodiment of the invention.

FIG. 2 is a plan view of a metal layer for describing various modified examples of a hole included in accordance with an embodiment of the invention.

FIGS. 3A to 3C are cross-sectional views of an insulating layer for describing a height at which the metal layer is interposed in the insulating layers, in accordance with an embodiment of the invention.

FIG. 4 is a cross-sectional view of a printed circuit board, in accordance with &second exemplary embodiment of the invention.

### DETAILED DESCRIPTION:

The present invention will now be described more frilly hereinafter with reference to the accompanying drawings, which illustrate embodiments of the invention. This invention may, however, be embodied in many different forms and should not be construed as limited to the illustrated embodiments set forth herein. Rather, these embodiments are provided so that this disclosure will be thorough and complete, and will fully convey the scope of the invention to those skilled in the art. Like numbers refer to like elements throughout. Prime notation, if used, indicates similar elements in alternative embodiments.

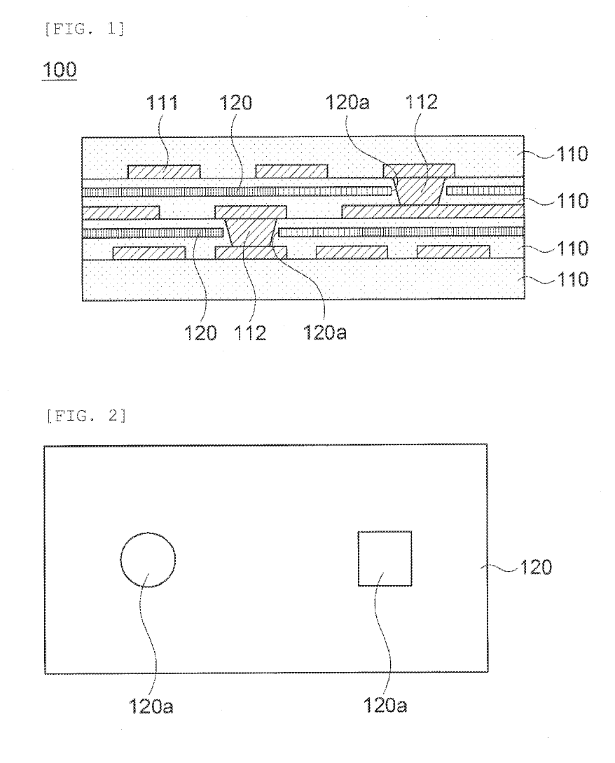

FIG. 1 is a cross-sectional view of a printed circuit, in accordance with a first embodiment of the invention. Additionally, components shown in the accompanying drawings are not necessarily shown to scale. For example, sizes of some components shown in the accompanying drawings may be exaggerated as compared with other components in order to assist in the understanding of the exemplary embodiments of the present invention. Meanwhile, throughout the accompanying drawings, the same reference numerals will be used to describe the same components. For simplification and Clarity of illustration, a general configuration scheme will be shown in the accompanying drawings, and a detailed description of the feature and the technology well known in the art will be omitted in order to prevent a discussion of the exemplary embodiments of the present invention from being unnecessarily obscure.

Referring to FIG. 1, a printed circuit board 100 according to an exemplary embodiment of the present invention is formed in a structure in which a plurality of insulating layers 110 having a metal wiring 111 formed on one surface thereof are stacked.

In accordance with an embodiment of the invention, as further shown in FIG. 1, the metal wiring 111 is made of a metal selected from a group consisting of copper, gold, silver, nickel, and an alloy thereof having excellent conductivity, and is classified into a ground wiring forming a ground region, a power wiring, which is a unit of supply power, and a signal wiring serving as an electrical passage to transfer a signal according to an application thereof.

In accordance with an embodiment of the invention, a material constituting the insulating layer 110 is appropriately selected by taking into account insulating property, heat-resisting property, moisture-resisting property, and the like. For example, as an optimal polymer material for forming the insulating layer 110, a thermosetting resin such as an epoxy resin, a phenol resin, a urethane resin, a silicon resin, a polyimide resin, or the like, and a thermoplastic resin such as a polycarbonate resin, an acrylic resin, a polyacetal resin, a polypropylene resin, or the like, is used. In addition to the above-mentioned materials, a curing agent increasing physical/chemical strength by curing (cross linked bonding) a polymer resin, a flame retardant giving flame retarding, other inorganic fillers, and the like is further included, according to various embodiments of the invention.

In accordance with an embodiment of the invention, as the insulating layer 110, prepreg (PPG) having a structure in which glass fiber is impregnated in the typical polymer resin composition described above is used. As the glass fiber, a glass base material used for a material of the printed circuit board, for example, E-glass, D-glass, R-glass, S-glass, NE-glass, and the like is used. The glass fiber has a form such as strand, yarn, roving, chopped strand, chopped strand mat, roving cloth, glass cloth, surfacing mat, or the like according to a processing form.

In accordance with an embodiment of the invention, as the insulating layer 110 in the printed circuit board according to the exemplary embodiment of the present invention, both the insulating layer made of the polymer resin composition (hereinafter, referred to as a build-up film since the insulating layer is typically manufactured in a build-up film form) and the prepreg having the structure in which the glass fiber is impregnated are used.

If the prepreg is used as the insulating layer 110, a structurally stable board is provided since the glass fiber provides mechanical strength and scale stability to the polymer resin. In addition, when the build-up film is used as the insulating layer 110, an SAP method is used due to excellent adhesion between the build-up film and the metal, thereby making it possible to implement a circuit of a fine line and space. However, since the build-up film has low modulus and a high coefficient of thermal expansion (CTE), it is vulnerable to warpage property of the board. Even though the prepreg is used, there is a limit in improving warpage of the board since the polymer resin is contained at a predetermined amount or more in the prepreg.

Therefore, according to an exemplary embodiment of the present invention, in order to improve warpage property of the board, the metal layer 120 is interposed in the insulating layers 110. Here, as a material of the metal layer 120, at least one of iron (Fe), nickel (Ni), tungsten (W), molybdenum (Mo), aluminum (Al), invar, or kovar having a low coefficient of thermal expansion and excellent thermal conductivity may be used. Particularly, since the invar has a slight change in physical property at temperature of 200° C. or less, it may be effective in improving warpage property of the board under a condition of high temperature.

In accordance with an embodiment of the invention, the metal layer 120 has a thickness, which is set in range of 5% to 35% of a thickness of the insulating layer 110. When the thickness of the metal layer 120 is too thin, an effect intended to be implemented according to the present invention is not produced. In contrast, when the thickness of the metal layer 120 is too thick, the total thickness of the board may be increased. Of course, it will be obvious to those skilled in the art that the above-mentioned numerical range may be changed within a scope of the present invention depending on the total thickness of the board or properties of the metal materials.

Meanwhile, in accordance with an embodiment of the invention, a via 112 for interlayer electrical connection of the metal wiring 111 is formed, so as to penetrate through the insulating layer 110. However, since the insulating layer 110 according to the exemplary embodiment of the present invention has the metal layer 120 made of the metal material therein, electrical short circuit between the via 112 and the metal layer 120 is caused.

In order to solve the electrical short circuit, according to the exemplary embodiment of the present invention, a hole 120a is perforated in the metal layer 120. The hole 120a is perforated at a position corresponding to the via 112 in the metal layer 120. Therefore, the via 112 my penetrates through the insulating layer 110 in a state in which it is inserted into the hole 120a.

Here, the hole 120a is perforated, so as to have a size larger than the via 112. Therefore, since the via 112 is inserted into the hole 120a, while not contacting the metal layer 120, the electrical short circuit between the metal layer 120 and the via 112 is prevented.

However, in the case in which e size of the hole 120a is too large, an area of the metal layer 120 is decreased, and in contrast, in the case in which the size of the hole 120 is too small, it is difficult to align the hole 120a with the via 112. Therefore, the size of the hole 120a is set n a range of approximately 1.1 times to 1.5 times of a diameter of the via 112.

In addition, as shown in FIG. 2, the hole 120a is perforated in various shapes such as a circular shape, an oval shape, or a polygonal shape including a quadrangle, but is not particularly limited to any particular shape. However, the via 112 is generally formed by filling a metal into a via hole perforated by laser irradiation and has a circular cross-section, Therefore, the shape of the hole 120a may also be the circular shape.

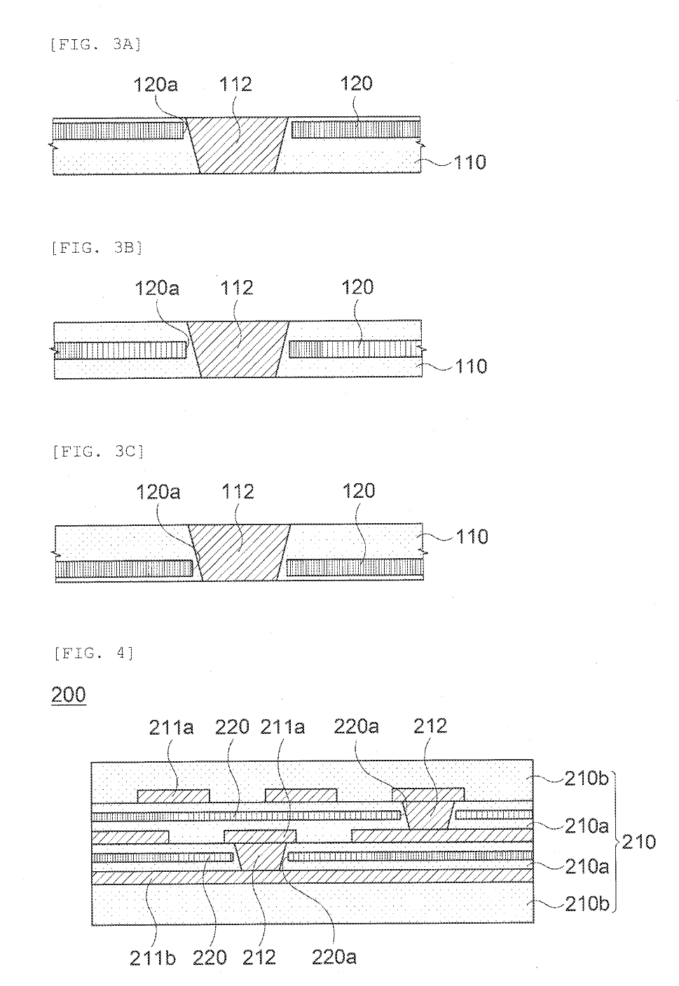

In addition, since a shape of a longitudinal section of the via 112 is formed to be tapered by the manufacturing process described above, the size of the hole 120a is also changed depending on a height at which the metal layer 120 is interposed in the insulating layers 110. For example, as shown in FIGS. 3A to 3C, as the metal layer 120 is interposed at a lower portion of the insulating layer 110, the hole 120a is formed, so as to have the size which is gradually decreased, thereby making it possible to maintain a constant interval between the hole 120a and the via 112.

Although the board having the structure in which the plurality of insulating layers are stacked is described by way of example, the present invention may be applied to a board having a symmetrical structure in which the insulating layer is built-up in both directions based on a core layer (here, the core layer may be a core layer made of a metal material, or a core layer made of the polymer resin having filler impregnated therein) or a board having one side structure in which the insulating layer is built-up only in one direction.

Hereinafter, a printed circuit board according to a second exemplary embodiment of the present invention will be described.

FIG. 4 is a cross-sectional view of a printed circuit board, in accordance with another exemplary embodiment of the invention. Referring to FIG. 4, a printed circuit board 200 according to a second exemplary embodiment of the present invention is formed in a structure in which a plurality of insulating layers 210 having metal wirings 211a and 211b formed on one surface thereof are stacked.

In accordance with an embodiment of the invention, the insulating layer 210 is configured by first insulating layers 210a made of a typical polymer resin composition and second insulating layers 210b made of a resin composition having glass fiber impregnated therein, and a metal layer 220 may be interposed in the first insulating layers 210a made of the resin composition.

In the printed circuit board 200 according to the second exemplary embodiment of the present invention, the metal layer 220 is interposed in the first insulating layers 210a, that is, the a build-up film made of the resin composition without the glass fiber impregnated therein, in the board having the structure in which the first insulating layer 210a made of the resin composition and the second insulating layer 210b made of the resin composition having the glass fiber impregnated therein. As described above, since the build-up film has excellent adhesion with the metal to be able to use the SAP method, it may implement the fine circuit, but is vulnerable to warpage property of the board. Therefore, the present invention makes an attempt at structural stability of the entire board by interposing the metal layer 220 having low thermal expansion property in the build-up film.

In accordance with an embodiment of the invention, the printed circuit board 200 according to the second exemplary embodiment of the present invention uses the build-up film in which the metal layer 220 is interposed as the insulating layer as the basis of the metal wiring 211a (e.g., a signal wiring) required to implement the fine circuit, and uses prepreg as the insulating layer that is the basis of the other metal wiring 211b (e.g., a ground wiring or a power wiring). As such, the printed circuit board 200 according to the second exemplary embodiment of the present invention implements the fine circuit and improve warpage property of the board by selectively applying the metal layer 220 according to the metal constituting the insulating layer 210.

In accordance with an embodiment of the invention, a via 212 for interlayer electrical connection is formed in the first insulating layers 210a, in which the metal layer 220 is interposed. In order to prevent electrical short circuit between the via 212 and the metal layer 220, a hole 220a is perforated at a position corresponding to the via 212 in the metal layer 220. The hole 220a has a diameter larger than the via 212. Therefore, the via 212 penetrates through the first insulating layer 210a in a state in which it is inserted into the hole 220a, while not contacting the metal layer 220.

In addition, similar to the first exemplary embodiment of the present invention, a size of the hole 220a is changed according to a height at which the metal layer 220 is interposed in the insulating layers 210. In this case, the hole 220a has a width in a range of 1.1 times to 1.5 times of a diameter of the via 212. In addition, the hole 220a has various shapes, such as a circular shape, an oval shape, or a polygonal shape including a quadrangle.

In accordance with an embodiment of the invention, the printed circuit board according to the exemplary embodiments of the present invention as described above improves warpage property of the board by using the insulating layers in which the metal layer is interposed. In addition, a thermal conductivity property that the prepreg or the build-up film, according to the related art does not have, is provided, such that heat radiation property which is recently required for a highly integrated board is also satisfied.

In addition, since the metal layer basically has a low thermal expansion property and a value of about 140 to 150 GPa in terms of elastic modulus, the entire strength of the board is significantly improved.

According to the exemplary embodiment of the present invention, the warpage property of the board is improved and the heat radiation property, which is recently required for a highly integrated board, is also satisfied.

In addition, by selectively using a metal layer according to the material constituting the insulating layer, the warpage property of the board is improved and the circuit of the fine line and space is implemented.

In addition, the entire strength of the board is significantly improved by using the metal layer having high elastic modulus.

Embodiments of the present invention may suitably comprise, consist or consist essentially of the elements disclosed and may be practiced in the absence of an element not disclosed. For example, it can be recognized by those skilled in the art that certain steps can be combined into a single step.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term, to describe the best method he or she knows for carrying out the invention,

As used herein, terms such as “first,” “second,” “one side,” “the other side” and the like are arbitrarily assigned and are merely intended to differentiate between two or more components of an apparatus, it is to be understood that the words “first,” “second,” “one side,” and “the other side” serve no other purpose and are not part of the name or description of the component, nor do they necessarily define a relative location or position of the component. Furthermore, it is to be understood that the mere use of the term “first” and “second” does not require that there be any “third” component, although that possibility is contemplated under the scope of the embodiments of the present invention.

The singular forms “a,” “an,” and “the” include plural referents, unless the context clearly dictates otherwise.

As used herein and in the appended claims, the words “comprise,” “has,” and “include” and all grammatical variations thereof are each intended to have an open, non-limiting meaning that does not exclude additional elements or steps.

Ranges may be expressed herein as from about one particular value, and/or to about another particular value. When such a range is expressed, it is to be understood that another embodiment is from the one particular value and/or to the other particular value, along with all combinations within said range.

Although the present invention has been described in detail, it should be understood that various changes, substitutions, and alterations can be made hereupon without departing from the principle and scope of the invention. Accordingly, the scope of the present invention should be determined by the following claims and their appropriate legal equivalents.

What is claimed is:

1. A printed circuit board, comprising:
a structure in which a plurality of insulating layers having a metal wiring formed on one surface thereof are stacked,
wherein a metal layer is interposed in the insulating layers.

2. The printed circuit board according to claim 1, further comprising:
a hole perforated in the metal layer and a via formed to penetrate through the insulating layers and be inserted into the hole.

3. The printed circuit board according to claim 2, wherein the hole has a size larger than a diameter of the via.

4. The printed circuit board according to claim 2, wherein the hole has a size in a range of 1.1 times to 1.5 times of a diameter of the via.

5. The printed circuit board according to claim 2, wherein the hole has a size changed according a height at which the metal layer is interposed in the insulating layers.

6. The printed circuit board according to claim 2, wherein the hole has at least one of a circular shape, an oval shape, or a polygonal shape including a quadrangle.

7. The printed circuit board according to claim 1, wherein the metal layer has a thickness in a range of 5% to 35% of a thickness of the insulating layer.

8. The printed circuit board according to claim 1, wherein the metal layer includes at least one of iron (Fe), nickel(Ni), tungsten (W), molybdenum (Mo), aluminum (Al), invar, or kovar.

9. A printed circuit board, comprising:
a structure in which a plurality of insulating layers having a metal wiring formed on one surface thereof are stacked,
wherein the insulating layer is configured by first insulating layers made of a resin composition and second insulating layers made of a resin composition having glass fiber impregnated therein, and a metal layer is interposed in the first insulating layers made of the resin composition.

10. The printed circuit board according to claim 9, further comprising:
a hole perforated in the metal layer and a via formed so as to penetrate through the first insulating layer and be inserted into the hole.

11. The printed circuit board according to claim 10, wherein the hole has a size larger than a diameter of the via.

12. The printed circuit board according to claim 10, wherein the hole has a size in a range of 1.1 times to 1.5 times of a diameter of the via.

13. The printed circuit board according to claim 10, wherein the hole has a size changed according to a height at which the metal layer is interposed in the first insulating layers.

14. The printed circuit board according to claim 10, wherein the hole has at least one of a circular shape, an oval shape, or a polygonal shape including a quadrangle.

15. The printed circuit board according to claim 9, wherein the metal layer has a thickness in a range of 5% to 35% of a thickness of the first insulating layer.

16. The printed circuit board according to claim 9, wherein the metal layer includes at least one of iron (Fe), nickel (Ni), tungsten (W), molybdenum (Mo), aluminum (Al), invar, or kovar.
